(19) United States
(12) Patent Application Publication
(10) Pub. No.: US 2015/0364685 A1
(43) Pub. Date: Dec. 17, 2015

(54) PROCESS FOR PATTERNING MATERIALS IN THIN-FILM DEVICES

(71) Applicants: John DeFranco, Rochester, NY (US); Mike Miller, Xenia, OH (US); Fox Holt, Dallas, TX (US)

(72) Inventors: John DeFranco, Rochester, NY (US); Mike Miller, Xenia, OH (US); Fox Holt, Dallas, TX (US)

(73) Assignee: Orthogonal, Inc., Ithaca, NY (US)

(21) Appl. No.: 13/985,194

(22) PCT Filed: Feb. 24, 2012
(86) PCT No.: PCT/US2012/026565

§ 371 Date: Nov. 12, 2013

Related U.S. Application Data
(60) Provisional application No. 61/448,724, filed on Mar. 3, 2011.

(51) Int. Cl. H01L 51/00; H01L 23/50; H01L 51/52; H01L 51/10; H01L 51/05; H01L 51/56

(52) U.S. Cl. CPC H01L 51/0018; H01L 51/0545; H01L 51/56; H01L 51/5206; H01L 51/5221; H01L 51/102; H01L 23/50; H01L 51/0017; H01L 51/5012

(57) ABSTRACT

A method for forming a device includes providing a substrate; depositing a single fluorinated photo-patternable layer over the substrate; forming a first and a second active layer over the substrate; and applying the photo-patternable layer to form a first pattern within the first active layer and a second, different pattern within the second active layer. Particular examples disclosed in the present disclosure can be employed to form thin film electronics devices, including OLED devices and TFTs with a reduced number of photolithographic steps.

This application is being filed on 24 Feb. 2012, as a PCT International Patent application in the name of Orthogonal, Inc., a U.S. national corporation, applicant for the designation of all countries except the U.S., and, John DeFranco, a citizen of the U.S., Mike Miller, a citizen of the U.S., and Fox Holt, a citizen of the U.S., applicants for the designation of the U.S. only, and claims priority to U.S. Patent Application Ser. No. 61/448,724 filed on 3 Mar. 2011, the disclosure of which is incorporated herein by reference in its entirety.

### BACKGROUND

The present disclosure provides a method for patterning active layers in devices to permit two, distinct, patterns to be formed in two or more different active layers following a single photolithographic step. This process can be employed to form multilayer, patterned organic or inorganic devices.

Various devices are known that employ patterned organic materials aligned to features or structures on a substrate. These devices are often considered to have the potential for low cost since organic materials are typically less expensive than inorganic materials and these organic materials can be rapidly blanket coated over large substrates, permitting the formation of large, low cost devices. One example of such a device is a display employing Organic Light Emitting Diodes (OLEDs). Besides providing the potential for low cost, these displays have the potential to produce light much more efficiently and with higher visual quality than most competitive display technologies. Therefore, OLED displays have the potential to displace LCD and plasma displays in many markets. This OLED technology can additionally be employed in other devices, including lamps with adjustable color. Similar device structures can be employed using organic semiconductors to form organic photovoltaic devices, organic memory devices and organic electrical components; such as organic Thin Film Transistors (oTFTs).

Unfortunately, OLED technology, particularly OLED display technology, has been adopted slowly. This slow adoption rate stems at least partially from the high cost of patterning these materials to form a practical display device. Various approaches to patterning organic materials to form full color OLED displays have been attempted. Patterning of different colors of material by vapor deposition of organic materials through shadowmasks has proven to be effective. However these shadowmasks limit the resolution of the displays, the size of the substrate that can be successfully coated, and increase the tact time. Other approaches, such as the use of laser deposition to pattern color emitters has been demonstrated but this technology often produces displays with low yields and often results in significant residual waste. Solution printing of different colored organic emitters has also been discussed but these processes typically result in emitters with significantly lower emission efficiency as compared to emitters deposited by vapor deposition. This lower efficiency is due to increased contact resistance and the fact that polymeric materials, that are often used, often have a lower luminescent efficiency and lifetime than small molecule materials and the use of solution deposition limits the number of layers that can be deposited on one another to manage the movement of carriers through the organic layer. Other approaches to forming multicolor OLED devices have also been attempted, including the use of white emitters together with patterned color filters. However, these approaches also reduce the effective efficiency of the emitters within the OLED display. Other organic devices, including oTFTs, suffer from similar patterning issues.

One approach to avoid detailed patterning of organic materials is to adopt OLED display structures including one or blanket-coated emitting layers. For example, Miller et al in U.S. Pat. No. 7,142,179, entitled “OLED display device”, issued on Nov. 26, 2006 and Cok et al in U.S. Pat. No. 7,250,722, entitled “OLED device”, issued on Jul. 31, 2007, each discuss a structure having a first OLED constructed between a first and a second patterned electrode and a second OLED constructed between the second patterned electrode and a blanket-coated electrode. Within each of these documents, the first OLED must be patterned to permit the second pattern electrode to be connected to the substrate. Further the second electrode must be patterned after it is deposited over the OLED. These structures produce higher efficiency light output without patterning at least one of the layers of organic materials. However, these structures require the patterning of very small structures through an organic layer to form a via hole through the organic material, as well as the patterning of a conductive layer over an organic layer. Robust processes for providing these vias and forming the electrode pattern over an organic layer in a high speed manufacturing environment are not known in the art and therefore these device structures have not been successfully manufactured. Similar structures are also desirable for the formation of multi-layer photovoltaic and other organic devices.

In inorganic electronic devices, it is known to apply photolithographic techniques to pattern multiple thin film layers of inorganic semiconductors and inorganic electrically conductive layers with high resolution over large substrates for forming arrays of electrical components. Unfortunately, the photolithographic materials and solvents applied to form these devices are known to dissolve organic materials. Therefore, it is not possible to apply the photolithographic materials and solvents that are known to be used to manufacture inorganic solid state circuits to pattern layers of organic material, especially layers that include active semiconductor organic materials or layers that are formed on top of organic materials.

Recently photoresist materials and solvents have been discussed in the art to facilitate the use of photolithographic techniques to pattern polymeric organic semiconducting layers. For example, Zakhidov et al. in an article published in Advanced Materials in 2008 on pages 3481-3484 and entitled “Hydrofluoroethers as Orthogonal Solvents for the Chemical Processing of Organic Electronic Materials” discusses a method for patterning polymer organic material in which a fluorinated photoresist is deposited on a substrate, selectively exposed to an energy source to crosslink a portion of the photoresist, the photoresist is developed in a solvent including hydrofluroether to develop the pattern and remove the portion of the photoresist material that was not cross-linked. The solubility of the cross-linked photoresist in a hydrofluroether was then reestablished through the use of another solvent. An active organic semiconductor was then deposited over the remaining photoresist and remaining photoresist was lifted off to pattern the active organic semiconductor. As such, this paper demonstrates the patterning of a single solution-coated, polymeric, organic semiconductor on a substrate. The same general process has been discussed by Lee et al. in an article published in the Journal of the American Chemical Society in 2008 on pages 11564 through 11565 and entitled “Acid-Sensitive Semiperfluoroalkyl Resorcinarene: An Imaging Material for Organic Electronics”.

Taylor et al. in an article published in Advanced Materials on Mar. 19, 2009 on pages 2314-2317 and entitled “Orthogonal Patterning of PEDOT:PSS for Organic Electronics using Hydrofluoroether Solvents” discusses the formation of a bottom contact thin film transistor in which a polymeric organic conductor (i.e., PEDOT:PSS) is formed on a substrate, a photoresist is formed and patterned over the conductor, the conductor is etched, a second photoresist is applied and patterned before an organic semiconductor (i.e., Pentacene) is applied and patterned.

Each of these papers discuss patterning of solution-coated, polymeric organic materials using a modified photolithographic process and materials to create components in an electrical circuit, the use of processes and materials such as these have not been applied to OLED devices. Further, these papers discuss the application of these materials and processes for use with polymers and do not provide a method for patterning layers of small molecule organic materials. Further, according to this method, it is necessary to perform multiple photo-patterning steps, specifically one photo-patterning step for each patterned layer, to create patterns in multiple layers including at least one organic layer and a layer deposited over this organic layer, such as an electrical conductor. Certain photolithographic process steps, including the exposure of the photolithographic materials to radiation to perform the photo-patterning step, are typically performed in air. Unfortunately, air contains oxygen and moisture with which the organic materials can react. Therefore, performing multilayer photo-patterning of organic devices by forming multiple layers of photo-patternable materials, some being formed over the organic layers can result in devices with degraded performance. Further, each of these photolithographic steps are quite expensive to perform and require one full photolithographic step, including deposition of the photo-patternable material, as well as, exposure, development and liftoff of the pattern for each layer within the device.

In another approach, Katz and Dhar in International Publication Number WO 2009/126916, entitled “Patterning devices using fluorinated compounds” filed Apr. 10, 2009 discuss forming an active layer to be patterned on a substrate, providing a barrier layer of fluorinated material over the active layer, forming a photo-patternable layer over the fluorinated layer and exposing the photo-patternable to radiation within a process that permits the active layer to be patterned. However, this approach requires the deposition of multiple layers to pattern a single active layer.

In another approach, Taussig et al in U.S. Pat. No. 7,202,179 entitled “Method of forming at least one thin film device”, issued on Apr. 10, 2007 discusses a method in which a 3D template is used to emboss a 3D structure over the layers of a device and the 3D structure and the underlying layers are etched to provide the final structure. This method permits different patterns to be formed in different layers of a device as the result of using a single imprint lithographic step so that alignment of multiple lithographic steps is not required, permitting this method to be applied to form devices on substrates that are not stable, for example, plastics which expand or contract during manufacturing. Unfortunately, the method provided is only useful with inorganic structures as the method applies materials and methods that are not compatible with organic semiconductor materials. Further, the method applies techniques that are not currently used in high volume manufacturing and requires strict process control to permit the patterning steps to achieve the desired result.

There is, therefore a need for a method that permits the formation of a first pattern in an organic material layer and at least a second, different pattern in a separate active material layer formed over the organic layer. This process should be robust, permit the formation of patterns at near micron resolution and not require the organic materials to be exposed to air during development. It is especially desirable that this method be compatible with vapor deposited, small molecule organic materials. Ideally, this same method would also be compatible with non-organic devices to permit multiple layers within these devices to be differently patterned in response to a single photolithographic step.

### SUMMARY

The present disclosure provides a method for forming a device that includes providing a substrate; depositing a single fluorinated photo-patternable layer over the substrate; forming a first and a second active layer over the substrate; and applying the photo-patternable layer to form a first pattern within the first active layer and a second, different pattern within the second active layer. Particular examples disclosed in the present disclosure can be employed to form thin film electronics devices, including OLED devices and TFTs with a reduced number of photolithographic steps.

Aspects of the present disclosure provide the advantage of permitting multiple layers within a device to be uniquely patterned through the deposition, exposure, and development of a single photosensitive material layer. This process can be applied in either organic or inorganic devices and enables the patterning of multiple layers, some of which are organic layers, within a device. As such, this method permits multilayer organic devices to be formed without removing the devices from inert environments during manufacture, permitting the formation of high quality organic device structures that were not previously possible in high volume manufacturing environments. Because many of the layers of a device can be patterned from a single exposure, aspects of the present disclosure also permit the manufacturing of thin-film devices on unstable, flexible substrates. Further this method has all of the advantages of traditional photolithographic methods, including providing a very high resolution (e.g., resolution on the order of a micron) in a highly parallel and therefore rapid process. Additionally this method permits devices to be performed with fewer photolithographic steps, significantly reducing total tact time, eliminating the need to deposit and develop multiple layers of photosensitive material during manufacture and therefore significantly reduces the cost of manufacture.

### BRIEF DESCRIPTION OF THE DRAWINGS

FIG. 1 flow diagram depicting the steps of an example an illustrative method of present invention;

FIG. 2 flow diagram depicting the detailed steps of an embodiment of the present invention;

FIG. 3 process diagram illustrating the steps of an example of the method of the present invention for forming an OLED display;

FIG. 4 process diagram illustrating the steps of an example of the method of the present invention for forming an array of TFTs; and

FIG. 5 flow diagram illustrating the steps of an example of the method of the present invention for forming an array of TFTs.

### DETAILED DESCRIPTION

Some embodiments of the current invention are discussed in detail below. In describing embodiments, specific terminology is employed for the sake of clarity. However, the invention is not intended to be limited to the specific terminology selected. A person skilled in the art can recognize that other equivalent components can be employed and other methods developed without departing from the broad concepts of the current invention.

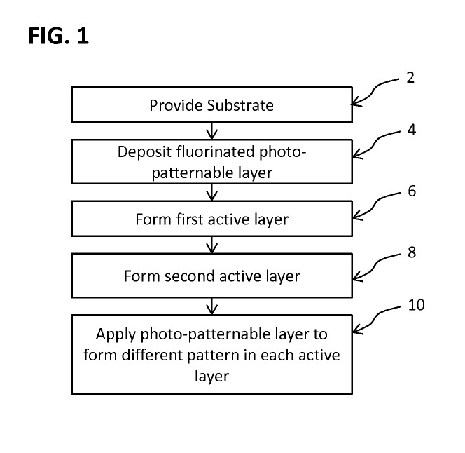

Aspects of the present invention provide a method for forming a thin film device as shown in FIG. 1. Thin film devices in certain instances of the present disclosure include devices having organic as well as inorganic thin film layers. Of particular importance, aspects of the present disclosure provide a method for forming a device that includes providing 2 a substrate, depositing 4 a single fluorinated photo-patternable layer over the substrate, forming 6, 8 a first and a second active layer over the substrate, and applying 10 the photo-patternable layer to form a first pattern within the first active layer and a second, different pattern within the second active layer. To permit different patterns to be provided in the first and second active layers, the photo-patternable layer can be exposed to radiation to create three unique, non-overlapping patterns of exposed material, depositing two material layers that are active or functional within the final device and applying the photo-patternable layer to impart different patterns into each of the two active material layers. These different patterns are typically imparted to the two active material layers by exposing the photo-patternable layer to a first fluorinated solvent to develop a first pattern and at least a second fluorinated solvent to develop at least a second pattern within the photo-patternable layer. A pattern in the fluorinated photo-patternable layer is typically transferred to an active material layer through liftoff or etching. When applying liftoff, the process steps can be ordered as shown in FIG. 1. However, this is not required. When applying etching, the fluorinated photo-patternable layer can be deposited 4 after the forming 6, 8 the first and the second active layers. According to the present disclosure, the photo-patternable layer can include a highly fluorinated material layer and the solvents can include highly fluorinated solvents.

Some embodiments of the method of the present invention rely upon two separate experimental observations that have been made by the inventors. First the inventors have observed that when a single fluorinated photo-patternable layer is deposited on a substrate and different portions of the fluorinated photo-patternable layer are exposed to different amounts of radiation, the portions having a lower exposure can be removed by a larger number of fluorinated solvents than the portions having a higher exposure. Therefore, by controlling the exposure and selecting the appropriate fluorinated solvents, different portions of the fluorinated photo-patternable layer can be removed at different times, permitting additional process steps to be completed between the times that these different portions are removed. Secondly, the inventors have observed that it is possible to form a bi-layer of a fluorinated photo-patternable layer and a traditional non-fluorinated photo-patternable layer wherein the two layers perform independently of one another without chemical interaction and in such a way that the exposure of the two layers can be differentially controlled. Further, when the non-fluorinated photo-patternable layer is removed over portions of the fluorinated photo-patternable layer, the exposed portions of the fluorinated photo-patternable layer can be lifted off much more quickly and easily than the portions of the fluorinated photo-patternable layer underlying the non-fluorinated photo-patternable layer. Thus the use of the bi-layer can provide additional differentiation in solvent sensitivity and provide the ability to form another region that can be removed at another time. The use of this bi-layer has another advantage when employing liftoff as removal of the portion of the fluorinated photo-patternable layer that is exposed by removing a portion of the non-fluorinated photo-patternable layer can result in a significant undercut profile for the remaining portions of the fluorinated photo-patternable layer.

These observations can be employed to create novel methods that can be applied to form complex thin film devices. For instance, certain examples of the methods of the present invention can be particularly advantageous to forming certain OLED device structures including OLED device structures such as the one discussed by Miller et al in U.S. Pat. No. 7,142,179. Additionally, the methods can be advantageous to forming certain TFT structures. More detailed embodiments for forming such devices will be provided within this disclosure.

To provide a clear and concise disclosure of certain examples of the method of the present invention, it is important to establish certain terminology for use within this disclosure. Within the present disclosure, an “organic device” is a device that contains an active layer that includes organic molecules (i.e., molecules containing hydrogen and carbon atoms). In certain embodiments, these organic molecules are organic semiconductors, such as Alq or organic conductors such as Pentacene. Conversely, an “inorganic device” is a device that contains no active layers which include organic molecules. An “active layer” is a layer that is functional within the device that is being constructed. Often in thin film electronic devices, such as the ones targeted by certain aspects of the present invention, the active layers can include a semiconductor or a conductor but can also include an insulator. An active layer can be a single homogenous layer but alternately can include multiple thin film layers that together form a functional layer within the device. For example, in an OLED, an active layer may include each of the organic layers within the diode, often including a hole transport or an electron transport layer. One of these layers or a separate, intermediate thin film layer can further provide light emission. Of relevance to certain aspects of the present invention, the handling of organic materials can require special care. The performance of some organic semiconductors can be significantly degraded through exposure to air or moisture. Further most organic materials are highly soluble in the non-fluorinated solvents applied in traditional photolithography and therefore it is not desirable to apply these solvents to devices after the deposition of organic materials. However, the organic materials are not soluble in typical highly fluorinated solvents and therefore these solvents can be applied after organic materials are deposited in a device.

Certain embodiments of the method of the present invention are applicable to “thin film” devices. These devices typically include layers that are less than 200 nm thick and often are less than 50 nm thick. Layers in thin film devices are often deposited using techniques such as evaporation, sputtering or solution coating. These devices are typically formed on a “substrate” which is a support for providing structural integrity to prevent the thin-film layers in the device from coming apart. The term “substrate” refers to any support on which thin film layers can be coated to provide structural integrity. Substrates known in the art include rigid substrates, such as those typically formed from glass, and flexible substrates, such as typically formed from stainless steel foil or plastic. The substrate can also provide a portion of an environmental barrier to protect any organic material from moisture or oxygen, but this is not required. The substrate can be opaque, transparent or semitransparent. The substrate can further include one or more layers, such as metal bus lines or inorganic semiconductor materials for conducting electricity to the device. The substrate can include nonconductive layers of organic material to perform functions, such as insulating the active layers from the substrate or conductive elements on the substrate. Nonconductive organic layers can also be included as part of the substrate when these layers are provided to smooth the surface of the substrate to permit a uniform layer of the thin film layers to be formed.

The term “etch” or etching within the present disclosure refers to a process in which the remaining portion or portions of a photo-patternable layer is used to protect the underlying regions of an active layer from exposure to a removal process. For example, remaining portions of the photo-patternable layer can protect portions of an active layer from a plasma stream which vaporizes the unprotected portions of an active organic layer, removing them from the substrate. Various chemistries and etching processes can be applied to remove different materials as known in the art and the etching methods can be selected or tuned to be selective having a large effect on a particular first material while having little or no effect on a different, second material. The term “liftoff” refers to a process in which the active layer is deposited over a portion of the photo-patternable layer and the substrate is exposed to a solvent that removes a portion of the photo-patternable layer, thus removing the overlying portion of the active layer.

When referring to a photo-patternable layer, the term “pattern” within the present disclosure refers to a spatial arrangement within the photo-patternable layer that differs in physical or chemical properties from other portions of the photo-patternable layer. However, when applied to an active layer, the term “pattern” refers specifically to a physical pattern that is created by removing a significant portion of the active layer in a specific pattern, creating a layer of varying thickness and ideally a layer which is present in some physical locations and not present within other physical locations. That is, when applied to an active layer, the term “pattern” refers to a spatial arrangement that is created by substantially removing a first portion of the active layer over some areas of the substrate while leaving a second portion of the active layer in substantially in tact over other areas of the substrate.

The term “expose” is applied in two different contexts within this document, specifically exposure to a solvent or exposure to radiation. Exposure to a solvent typically involves immersion in a solvent, simultaneously or uniformly coating the entire substrate in the solvent. However, the term “expose” when applied to radiation applies to a process in which the dose or exposure degree of radiation is controlled and typically varied across the substrate so that some regions receive a larger dose than others. This can be accomplished by any of multiple methods, including exposing the substrate to multiple exposures with different masks, exposing the substrate through a grayscale photomask that lets through different amounts of light in different places, exposing the substrate through laser patterning in which the intensity or dwell time is varied or by laser exposure using a holographic means, by which all or (more likely) an element of the pattern is exposed with all of the different areas within the pattern receiving the proper amount of light. This last method can be combined with laser patterning on a roll-to-roll format, when forming repeated elements such as backplane transistors. That is, a laser can be imaged through a holographic film to create a pattern having multiple exposure areas on the substrate while the laser is imaged in a fixed position with respect to the substrate and can image one or more elements (e.g., TFTs or OLED pixels), the laser can then moved to a different location on the substrate and used to image another element or group of elements. In the OLED application, the area over the via holes and around each element would be defined at this time.

The term “electrode” refers to layer or a combination of multiple thin film layers which functionally provide a single conductive layer capable of creating an electrical field within the thin film layers of the device. An electrode can be transparent, semi-transparent, or opaque. However, at least one of a first or second electrode in the OLED devices of the present disclosure can be transparent or semi-transparent. Often one of the first or second electrodes within devices in certain embodiments of the present invention can be opaque and reflective. Typical electrodes useful in certain embodiments of the present invention can have a thickness of between 10 and 300 nm. Electrodes can be formed from organic or inorganic materials capable of conducting electricity to create an electric field within the thin film layers of the devices in certain embodiments of the present invention. Typical inorganic materials useful in forming an electrode can include metals such as silver, gold, platinum, copper, molybdenum and aluminum; as well as certain doped metal oxides, such as indium tin oxide or indium zinc oxide. Electrodes can be formed using multiple methods including printing or sputtering. However, it is desirable in certain embodiments to deposit the inorganic materials to form an electrode using evaporation or other methods that provide line of sight deposition. Organic materials useful in forming an electrode include highly ordered polymers, such as PEDOT/PSS. Electrodes can be formed using numerous methods, including printing methods. However, to increase deposition speed and decrease process time, it is preferred that the material used to form electrodes, especially the material used to form the second electrode be deposited using blanket-coating methods to form a continuous film over the substrate.

The term “patterned electrode” refers specifically to electrodes that are segmented across the substrate such that each segment of the electrode is shared by one or more electrical component or light-emitting elements but all electrical components or light-emitting elements on the substrate do not share the same segment of the electrode. That is, the flow of current through any two segments of the electrode can be independently controlled to independently control the flow of current through the electrical component or light-emitting element that is in contact with each segment.

The fluorinated photoresist material which is applied to form the “fluorinated photo-patternable layer” can be a resorcinarene, a copolymer of perfluorodecyl methacrylate and 2-nitrobenzyl methacrylate, derivatives thereof or other polymer photoresist or molecular glass photoresist having sufficient content to permit the photoresist to be dissolved in a fluorinated solvent such as a solvent formed from a hydrofluorether. This fluorinated photoresist can be solubulized in a hydrofluroether such as methyl nonafluorobutyl ether and then coated onto a substrate. The solvent can then be evaporated to form a photo-patternable layer. This solvent can also include a photo-acid generator, for example N-hydroxynaphthalamide perfluorobutylsulfonate or other known photo-acid generator. In the presence of proper exposure, this photo-acid generator can liberate H+, which can react with the fluorinated photoresist material to transform it into an insoluble form. These materials and their use in conjunction with fluorinated solvents for performing photolithographic steps have been discussed in more detail in a co-pending document with the serial number PCT/US09/44863 and entitled “Orthogonal Processing of Organic Semiconductors”.

In another embodiment this photoresist can be a material composed of a copolymer of 1H,1H,2H,2H-perfluorodecyl methacrylate (FDMA) and tert-butyl methacrylate (TBMA). This material was found to have a high enough fluorine content to make it soluble in fluorinated solvents in certain embodiments of the present invention. This statistical copolymer of FDMA and TBMA was prepared by free radical polymerization under a nitrogen atmosphere. A 25 ml round bottom flask equipped with a stir bar was filled with 1.4 g of FDMA, 0.6 g of TBMA, 0.01 g of AlBN and 2 ml of trifluorotoluene as a solvent. After polymerization, the reaction mixture was poured into hexane to precipitate the polymer and then filtered and dried under vacuum. The molecular weight of the copolymer was determined to be 30400 by size-exclusion chromatography and the molar composition of FDMA:TBMA was found to be 35 mol %:65 mol % using 1H NMR (Varian Inova-400 spectrometer) analysis with CDC1₃-CFC1₃ (v/v-1:3.5) as a solvent. The FDMA component of the resist is responsible for the solubility of the copolymer in fluorinated solvents whereas the TBMA groups in the unexposed regions make the copolymer less polar in the butyl-protected state. Upon exposure to a photo-generated acid, these protecting groups undergo a chemically amplified deprotection reaction. The resulting polar methacrylic acid (MAA) units decrease copolymer solubility in fluorinated solvents. After the photo-patternable layer is formed from this material together with a photoacid generator and exposed, the exposed pattern can be treated with a solubilizing agent, for example a silazine such as HMDS. This treatment re-protects the P(FDMA-co-MAA) film with siloxane groups and makes it soluble within selected fluorinated solvents to facilitate its removal for liftoff.

It should be noted that the resorcinarene and FDMA:TBMA copolymer are chemically amplified resists. Within certain embodiments of the present invention, this attribute of these resists can be particularly desirable since they enable the expose photoresist step to be performed through the application of a relatively low energy UV light exposure (typically under 100 mJ/cm²). This is particularly important in devices employing organic compounds which are deposited before the fluorinated photo-patternable layer is deposited 4 since many organic materials useful in forming the one or more organic layers can decompose in the presence of UV light and therefore, reduction of the energy during this step permits the photoresist to be exposed without causing significant damage to the underlying one or more organic layers. Further, due to the high fluorine content in each of these photoresists, they are both hydrophobic and oleophobic.

Fluorinated solvents appropriate for use of the first, second or third fluorinated solvent is perfluorinated or highly fluorinated liquids, which are typically immiscible with organic solvents and water. Among these solvents are one or more hydrofluoroethers (HFEs) such as methyl nonafluorobutyl ether, methyl nonafluoroisobutyl ether, isomeric mixtures of methyl nonafluorobutyl ether and methyl nonafluoroisobutyl ether, ethyl nonafluorobutyl ether, ethyl nonafluoroisobutyl ether (HFE 7100), isomeric mixtures of ethyl nonafluorobutyl ether and ethyl nonafluoroisobutyl ether (HFE 7200), 3-ethoxy-1,1,1,2,3,4,4,5,5,6,6,6-dodecafluoro-2-trifluoromethyl-hexane (HFE 7500), 1,1,1,2,2,3,4,5,5,5-decafluoro-3-methoxy-4-trifluoromethyl-pentane, 1,1,1,2,3,3-hexafluoro-4-(1,1,2,3,3,3,-hexafluoropropoxy)-pentane (HFE 7600) and combinations thereof. The fluorinated solvent may also be selected from a broad range of fluorinated solvents, such as chlorofluorocarbons (CFSs): CₓCl_{y}F_{z}, hydrochlorofluorocarbons (HCFCs): CₓCl_{y}F_{z}H_{w}, hydrofluorocarbons (HFCs): CₓF_{y}H_{z}, purfluorocarbons (FCs); CₓF_{y}, hydrofluoroethers (HFEs): CₓH_{y}OC_{z}F_{w}, perfluoroethers: CₓF_{y}OC_{z}F_{w}, purfluoroamines: (CₓF_{y})₃N, trifluoromethyl (CF3)-substituted aromatic solvents: (CF3)xPh [benzotrifluoride, bis(trifluoromethyl)benzene]. Other fluorinated solvents are also known and could be equally well applied for use in the first, second, or third fluorinated solvent.

The photoresist solution can typically include the photoresist material as described above in a fluorinated solvent, for example HFE 7500. Additionally, when the photoresist is a chemically amplified resist material, such as a resorcinarene or the FDMA/TBMA copolymer, this solution can additionally contain a photoacid generator. An appropriate photoacid generator is 2-[1-methoxy]propyl acetate (PGMEA).

Generally, it is desirable that solvent in which the photoresist is dissolved have a higher boiling point than the first, second, or third fluorinated solvents. Generally, the fluorinated solvent applied to form the photoresist solution can have a boiling point above 110 degrees Celsius while the second and third fluorinated solvents can have a boiling point below 110 degrees Celsius. For example, the solvent in the fluorinated solvent can include HFE 7500 having a boiling point of 131 degrees Celsius at atmospheric pressure while the first, second and third solvents can include HFE 7200 having a boiling point of 76 degrees Celsius at atmospheric pressure. The selection of these boiling points in this way is useful to reduce any of the first fluorinated solvent remaining after the first baking step from being evaporated during later baking steps, which would reduce the dimensional stability of the first pattern of exposed photoresist material. Further, any baking or drying step performed after the fluorinated photoresist is spun onto the substrate should be performed at a temperature less than the boiling point of the fluorinated solvent in which the fluorinated solvent is dissolved.

The first, second and third fluorinated solvents can include a solubilizing agent to permit the pattern of exposed photo-patternable material to become soluble in the fluorinated solvent. For example, materials such as a silazine, for example hexamethyldisilazane (HMDS; 1,1,1,3,3,3-hexamethyldisilazane) can be added to the first, second and third fluorinated solvents to render the patterns of exposed fluorinated photo-patternable layers soluble. Such an agent can be added to a fluorinated solvent to form the second and third solvents, for example the third solvent can contain 5% HMDS and 95% HFE 7200. Other useful solubilizing agents include isopropyl alcohol (IPA) which can be formulated similarly to form a third solvent containing 5% IPA and 95% HFE 7200.

In certain embodiments of the present invention the first, second and third fluorinated solvents can have different reactivity levels with the first fluorinated solvent being weaker than the second or third fluorinated solvent and the second fluorinated solvent being weaker than the third fluorinated solvent. For example, the first fluorinated solvent can be HFE 7300 (commercially available from 3M as Novec 7300), the second fluorinated solvent can be FIFE 7600 (commercially available from 3M as Novec 7600) and the third fluorinated solvent can be HFE 7200 (commercially available from 3M as Novec 7200). The first and second fluorinated solvents can contain 5% HDMS and the third fluorinated solvent can contain 5% Isopropyl Alcohol (IPA).

As noted earlier, a portion of the photoresist can be exposed to radiation to form patterns of exposed fluorinated photoresist material and a second pattern of unexposed photoresist material. For example, an ultraviolet lamp having a wavelength of 248 nm can be used to radiate the photoresist or a lamp with another wavelength, for example 365 nm can be applied. Experiments have verified that when the photoresist is formed from resorcinarene, an exposure of 84 mJ cm² at 248 nm is adequate to enable at least a first level of exposure the necessary reaction while a dose of 2700 mJ cm² is required when the wavelength is 365 nm. Higher levels of exposure can be applied to create additional exposure levels.

The term “non-fluorinated photo-patternable layer” applies to any photo-patternable layer that does not contain highly fluorinated compounds. This is necessary to avoid a reaction between the materials used to form this layer and the “fluorinated photo-patternable layer” which is formed using the fluorinated photoresist materials as described earlier. This photo-patternable layer can be formed, for example, using any of the known standard photoresist materials as long as the chemistry does not interact with the fluorinated photo-patternable layer. These layers can include Shipley resists, such as NLOF 2020 (made by Dow) or SU-8 (made by MicroChem). It is not necessary that the resist be strippable after patterning, in many embodiments liftoff can occur on the sacrificial fluorinated resist layer which can be deposited before the non-fluorinated photo-patternable layer. The formation of the non-fluorinated photo-patternable layer can include a post-apply baked (PAB) as well as a deposition step. It is important for this step that the PAB for the top resist layer not be applied at a greater temperature or with a longer duration than is applied during the formation of the fluorinated photo-patternable layer, since this may cause solvent from the fluorinated photo-patternable layer to form bubbles in the non-fluorinated photo-patternable layer. The term “non-fluorinated solvent” applies to any non-fluorinated solvent which can be used to dissolve the non-fluorinated photo-patternable layer without interacting with the fluorinated photo-patternable layer. The inventors have demonstrated that both SU-8 chemistries (gamma butyrolactone) and tetramethyl ammonium hydroxide (TMAH) satisfy these requirements.

It should be noted that the detailed embodiments as described below provide the important high level steps necessary to the method in certain embodiment of the present invention. One skilled in the art will recognize, however, that forming or depositing either a fluorinated or non-fluorinated photo-patternable layer can include solution coating of a photoresist onto the substrate using methods such as spin coating and drying of this solution which can include a post-apply bake step. Exposing either of these photo-patternable layers can include selective exposure of the substrates to a radiation source such that different areas of the substrate receive at least three substantially different exposure levels and can further employ a post exposure bake to activate the chemical processes in the photo-patternable layers.

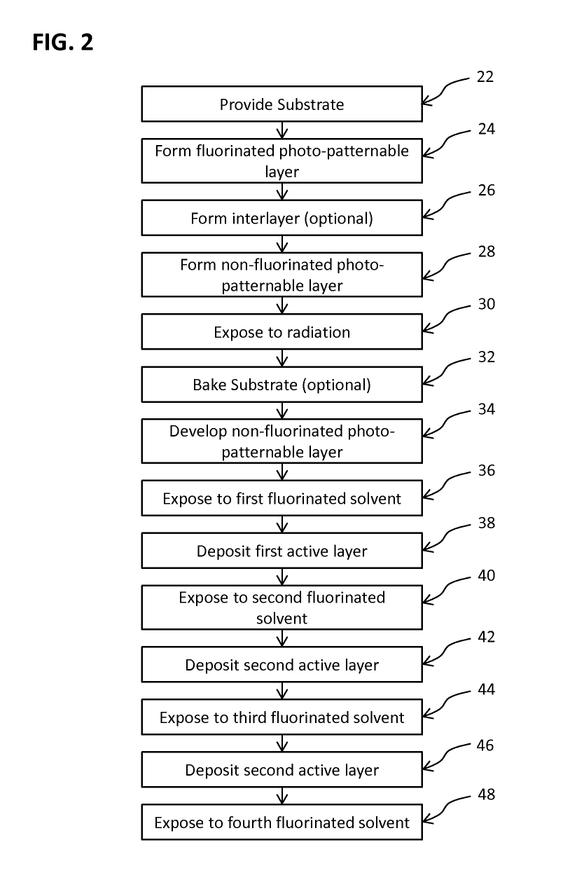

Having defined the terminology relevant to certain embodiments of the present invention, certain detailed embodiments of the present invention can now be provided. In a first detailed embodiment, the method in certain embodiments of the present invention is applied to form a generic device having at least two active layers that each receive a distinct pattern as a result of depositing photolithographic materials to form a single photo-patternable layer, exposing these materials to varying levels of radiation to create multiple patterns of material within the photo-patternable layer, depositing two or more active layers and developing different patterns to create different patterns within at least two of the active layers. FIG. 2 provides a flow diagram indicating the steps of this process.

As shown in this flow diagram, a substrate is provided 22. A layer of fluorinated photoresist is deposited onto the substrate and dried to form 24 a first fluorinated photo-patternable layer. This fluorinated photoresist can be a negative tone resist, such as Ortho 310 commercially available from Orthogonal Inc, but it could also be a positive tone resist. The substrate in this example can be either bare or with one or more patterned or unpatterned layers deposited before the photoresist. This fluorinated photoresist should have the property that it can receive varying amounts of UV light within its sensitivity range and, if chemically amplified, as is Ortho 310, varying amounts of post-exposure bake (PEB) temperature and time, to control the amount of solubility switching it receives in various parts of the deposited film. Once it is deposited, this first layer of fluorinated photoresist is baked to remove any residual solvents.

An optional interlayer can then be deposited over the fluorinated photo-patternable layer to promote adhesion of following layers or to provide a photo-bleaching interlayer and dried to form 26 an optional interlayer. A second photoresist, specifically a non-fluorinated photoresist is deposited on top of the fluorinated layer to form 28 a non-fluorinated photo-patternable layer. In the current embodiment, this non-fluorinated photo-patternable layer is assumed to also be a negative tone photoresist. However, this is not necessary and this non-fluorinated photo-patternable layer can have the same or a different tone than the fluorinated photo-patternable layer. This non-fluorinated photoresist layer is post-apply baked as well to remove any unwanted solvents. It is important for this step that the temperature applied for the post-apply bake for the non-fluorinated photoresist not exceed the temperature applied for the post-apply bake for the fluorinated photoresist layer, otherwise any additional solvent in the first photo-patternable layer can be vaporized and form bubbles in the non-fluorinated photoresist layer. Together, the fluorinated and non-fluorinated photo-patternable layers form a photo-patternable bi-layer, which contains a single layer of fluorinated photoresist material.

The photo-patternable bi-layer is then exposed 30 to UV light or radiation at a wavelength in which both resists are sensitive. The dose is varied across the substrate so that some regions or areas of the substrate receive a larger dose than other areas. Although it is preferable to expose both bi-layers with UV light having a single peak wavelength, it is also possible to expose the substrate with radiation that has multiple peak wavelengths or to provide multiple exposures. For example, the radiation or each exposure can have a different peak wavelength, one wavelength selected to expose the fluorinated photoresist and a second wavelength selected to expose the non-fluorinated photoresist. Through this process, the photo-patternable bi-layer can be controlled to provide three to five or even more distinct exposure regions, each having a different pattern. The inventors have observed the ability to control this process to create:

a first pattern including areas where neither the fluorinated or the non-fluorinated photo-patternable are exposed;

a second pattern including areas where the non-fluorinated photo-patternable layer is rendered insoluble to a standard developer and the fluorinated photo-patternable layer remains substantially unexposed;

a third pattern including areas where the non-fluorinated photo-patternable layer is rendered insoluble to the standard developer and the fluorinated photo-patternable layer is insoluble to a first fluorinated solvent but soluble in a second fluorinated solvent as well as a fluorinated liftoff or third fluorinated solvent;

a fourth pattern including areas where the non-fluorinated photo-patternable layer is rendered insoluble to the standard developer and the fluorinated photo-patternable layer is insoluble to the second fluorinated solvent but soluble in the fluorinated liftoff or third fluorinated solvent; and

a fifth pattern including areas where the non-fluorinated photo-patternable layer is rendered insoluble to the standard developer and the fluorinated photo-patternable layer is soluble in the fluorinated liftoff or third fluorinated solvent.

That is, the inventors have observed that each of these patterns can be created and further, their removal can be controlled through exposure of these patterns to different solvents as indicated.

As noted earlier, to robustly create the second pattern, it can be useful to deposit a photo-bleaching layer between the fluorinated photo-patternable layer and the non-fluorinated photo-patternable layer to form 26 an optional interlayer. This photobleaching interlayer can be the same or a similar photobleaching layer as is commonly used in high-resolution lithography as a resolution enhancement layer. The function of this layer is to absorb a certain amount of light before bleaching and permitting the ultraviolet radiation to pass through and encounter the fluorinated photo-resist layer. An additional benefit of such a layer can be to enhance the adhesion of the resist layer to the fluorinated layer.

The first, the second, and the third or liftoff fluorinated solvents can all be highly fluorinated and can all be hydrofluoric ether (HFE). The first fluorinated solvent can be Novec 7300, the second fluorinated solvent can be Novec 7600 and the liftoff solvent can be Novec 7200+IPA. It is important that the second solvent be more reactive than the first solvent and that the liftoff solvent be more reactive than the second solvent, such that these solvents can be applied to remove the patterns with increasing exposure. Note that the standard developer is not a highly fluorinated solvent and therefore this solvent can have little or no effect on the material within the second, third, fourth, or fifth patterns.

After exposure to radiation, the substrate can be optionally baked 32 to cure the photo-patternable layers. This step is particularly important when the fluorinated photo-patternable layer or the non-fluorinated photo-patternable layer is a chemically amplified resist. This post exposure bake can often be performed at a temperature that is less than the temperatures used for either of the post apply bake steps discussed earlier.

The non-fluorinated photoresist is then developed 34 to remove the non-fluorinated photoresist within the first pattern without removing the non-fluorinated photoresist in the second pattern. This develop 34 step is performed by exposing the substrate to a non-fluorinated solvent that serves as a solvent for the non-fluorinated photo-patternable layer. For example, the substrate can be exposed to SU-8 chemistries such as gamma butyrolactone or tetramethyl ammonium hydroxide (TMAH). Each of these solvents have been shown to develop traditional non-fluorinated photoresists without affecting the fluorinated resist within the fluorinated photo-patternable layer.

The substrate can then be exposed 36 to a first fluorinated solvent to remove the unexposed fluorinated photo-patternable layer within the first and second patterns. This exposure can create an undercut under the non-fluorinated photo-patternable layer, which can be desirable for future liftoff steps. Each of these steps can be performed in a variety of environments, including open air or a near atmospheric pressure dry nitrogen environment. Note also, it is possible to divide this step 36 into two separate steps, including exposing the substrate to the first fluorinated solvent for a first time period to remove the unexposed fluorinated photo-patternable layer within the first pattern, and then exposing the substrate to the first fluorinated solvent for a second time period to remove the exposed fluorinated photo-patternable layer within the second pattern. Active material layers can be deposited between these steps to provide a patterned layer.

A first active layer can then be deposited 38 over the substrate. This first active layer might be, for example, a conductive layer. This deposition process can be performed within an inert environment, including a vacuum or dry nitrogen environment. The substrate can then be exposed 40 to a second fluorinated solvent to remove the fluorinated photo-patternable layer within the third pattern. This step can liftoff the non-fluorinated photo-patternable layer within the third pattern as well as the portion of the first active layer that is deposited over the third pattern, thus this exposure creates a pattern within the first active layer. This exposure can be performed within a dry nitrogen environment in a near-atmospheric environment.

A second active layer can then be deposited 42 over the substrate. This second active layer might be, for example, an organic semiconductor. This deposition process can also be performed within an inert environment. The substrate can then be exposed 44 to a third fluorinated solvent to remove the fluorinated photo-patternable layer within the fourth pattern. This step can liftoff the non-fluorinated photo-patternable layer within the fourth pattern as well as the portion of the second active layer that is deposited over the fourth pattern, thus this exposure creates a pattern within the second active layer that is different than the pattern created within the first active layer. This exposure can be performed within a dry nitrogen environment at near-atmospheric pressure.

A third active layer can then be deposited 46 over the substrate. This third active layer might be, for example, a second conductor. This deposition process can also be performed within an inert environment. The substrate can then be exposed 48 to a liftoff solvent to remove the fluorinated photo-patternable layer within the fifth pattern. This step can liftoff the non-fluorinated photo-patternable layer within the fifth pattern as well as the portion of the third active layer that is deposited over the fifth pattern, thus this exposure creates a pattern within the third active layer. This exposure can be performed within a dry nitrogen environment at near-atmospheric pressure.

When at least one of the active layers contain organic materials, these steps provide a method for forming an organic device by depositing a fluorinated photo-patternable layer over a substrate, forming a first and a second active layer over the substrate where at least one of the first or second active layers including an active organic layer and applying the photo-patternable layer to form a first pattern within the first active layer and a second, different pattern within the second active layer. However, these steps also provide a method for forming a device that includes depositing a fluorinated photo-patternable layer over a substrate; depositing a non-fluorinated photo-patternable layer over the substrate; exposing the fluorinated photo-patternable layer and the non-fluorinated photo-patternable layer to a radiation source providing three or more distinct levels of radiation, including at least a first pattern including areas where neither the fluorinated or the non-fluorinated photo-patternable are exposed, a second pattern including areas where one of the non-fluorinated photo-patternable layer and the fluorinated photo-patternable layer are exposed and the remaining layer remains substantially unexposed, and a third pattern including areas where both the non-fluorinated photo-patternable layer and the fluorinated photo-patternable are exposed; forming a first and a second active layer over the substrate; exposing the substrate to a non-fluorinated solvent to remove a portion of the non-fluorinated photo-patternable layer; and exposing the substrate to a fluorinated solvent to remove a portion of the non-fluorinated photo-patternable layer to create a first spatial pattern within the first active layer and a second, different spatial pattern within the second active layer.

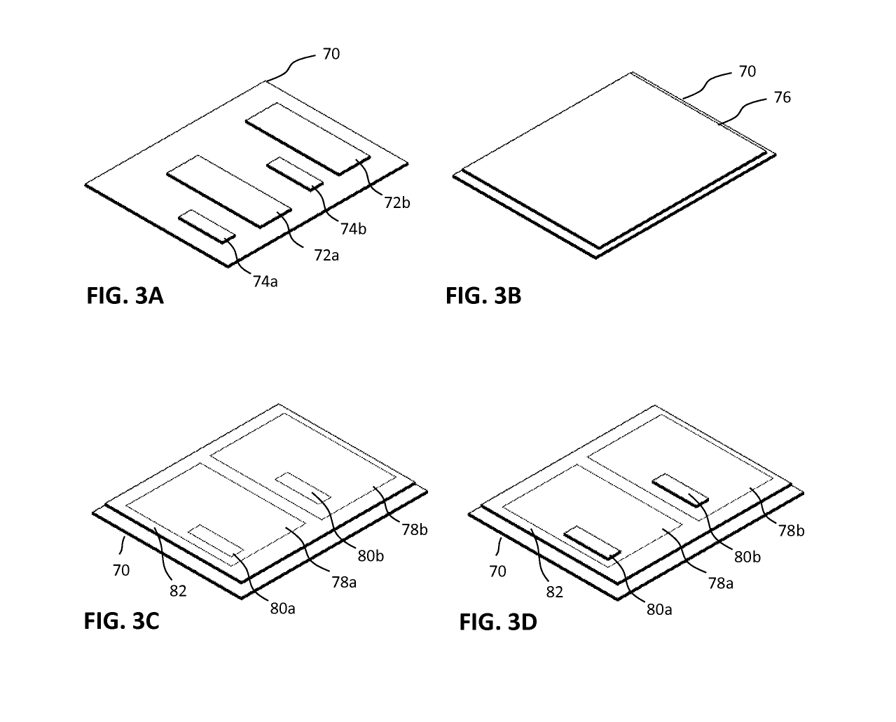

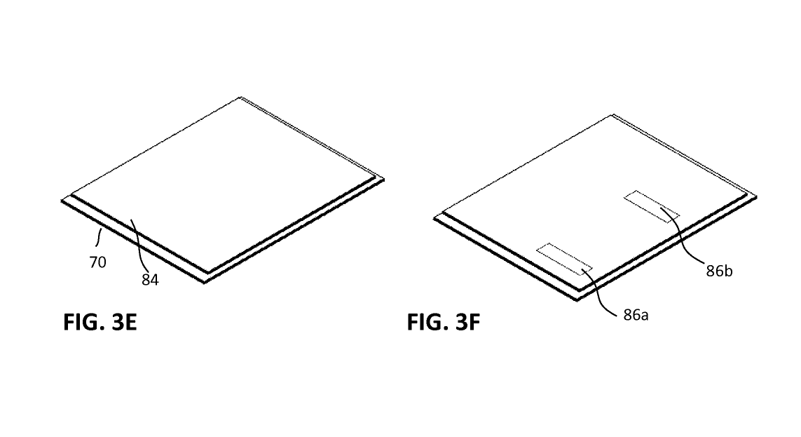

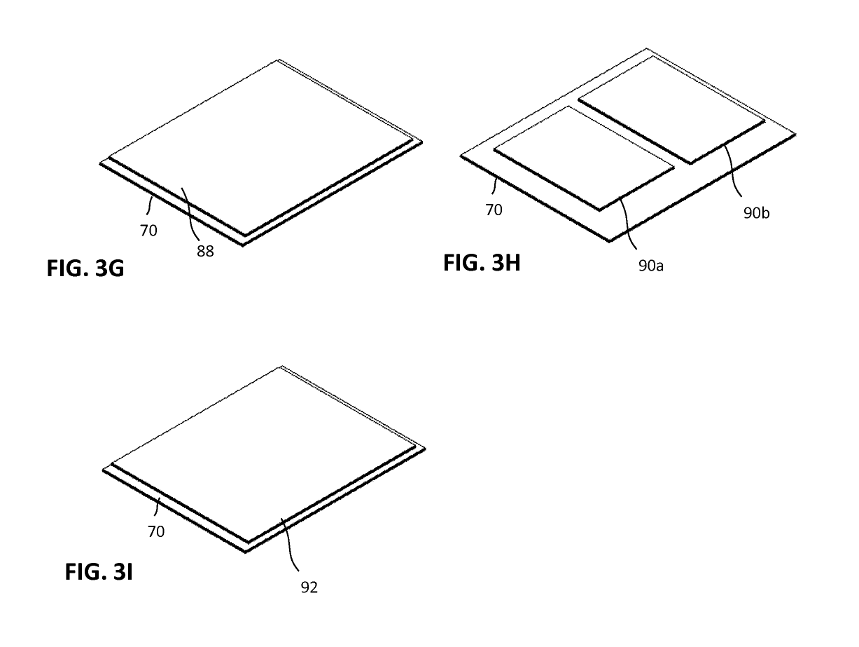

The previous detailed embodiment provided the basic steps of an embodiment of the present invention. However, to illustrate the value of such a method, it is also useful to discuss this method in the context of constructing specific devices. Therefore, in an alternate embodiment, a method is provided for constructing an OLED display device having two addressable light-emitting layers. The construction of this device structure is illustrated within the process flow diagram of FIG. 3.

Within this embodiment, a substrate 70 is provided as shown in FIG. 3A. This substrate 70 can include active matrix driving circuits (not shown) for providing current to OLED devices. These circuits can be connected to power busses on the substrate (not shown) for providing current to the OLEDs that are connected to external power supplies and drivers for controlling the state of the circuits to control the flow of power from the power busses to the OLED. These circuits can be connected to conductive elements 72a, 72b, 74a, 74b on the surface of the substrate 70 where these conductive elements include an array of one or more electrodes 72a, 72b for sourcing or delivering current from an OLED within the first addressable light-emitting layer and an array of one or more via connectors 74a 74b for sourcing or delivering current to or from OLEDs in both the first and second addressable light-emitting layers. The entire substrate 70, with the exception of these conductive elements 72a, 72b, 72c, 72d will typically be covered with an insulating layer (not shown), which can serve as a pixel definition layer. The edges between this insulating layer and the conductive elements 72a, 72b, 74a, 74b can have a vertical profile that includes a taper from the thickest part of the insulating layer to the conductive element 72a, 72b, 74a, 74b where the taper has a slope of 45 degrees or less and the insulating layer can overlap the edges of each conductive elements 72a, 72b, 74a, 74b. This structure is well known for short reduction in existing, single layer OLED structures. A photo-patternable layer 76 can then be formed over the substrate as shown in FIG. 3B and the conductive elements 72a, 72b, 74a, 74b. The formation of this photo-patternable layer can include the formation of a bi-layer of fluorinated and non-fluorinated photoresist materials as discussed earlier and shown in FIG. 2 in steps 24 through 28.

Once the photo-patternable bi-layer is formed, the photo-patternable bi-layer is exposed 50 to radiation to create three unique patterns of material. The first pattern includes of the areas 78a and 78b as shown in FIG. 3C and is exposed such that neither the fluorinated nor the non-fluorinated photo-patternable are exposed within the areas 78a and 78b. The second pattern includes areas 80a and 80b. This pattern is exposed such that the non-fluorinated photo-patternable layer is rendered insoluble to the standard developer and the fluorinated photo-patternable layer is soluble in either a first fluorinated solvent or a second fluorinated solvent. The third pattern includes area 82 which is exposed such that the non-fluorinated photo-patternable layer is rendered insoluble to the standard developer and the fluorinated photo-patternable layer is insoluble in the first fluorinated solvent but soluble in the second fluorinated solvent within specified exposure conditions.

The substrate is then exposed to the non-fluorinated developer to remove the non-fluorinated photo-patternable layer in the first pattern, including areas 78a and 78b. The substrate is then exposed to a fluorinated developer to remove the fluorinated photo-patternable layer in the first pattern, including areas 78a and 78b. Through this step both the fluorinated and non-fluorinated photo-patternable layers are removed from the substrate in the first pattern, including areas 78a and 78b as shown in FIG. 3D. Further, these exposure steps can provide sidewalls in the remaining photo-patternable bi-layer that are undercut with a small portion of the fluorinated photo-patternable layer removed from under the remaining non-fluorinated photo-patternable layer. Thus subsequent blanket coated layers can generally not be deposited in the areas shadowed by the top of this undercut profile. Note that in traditional devices, the substrate 70, the conductive elements 72a, 72b, 74a, 74b and any insulating layers, as well as the photo-patternable layers are generally not susceptible to contamination in uncontrolled atmospheric environments as the materials are generally not highly reactive to oxygen or moisture. Note that the primary function of this step is to expose the one or more electrodes 72a and 72b, as well as the area around the one or more vias 74a, 74b.

Within this device structure, an organic light-emitting layer 84 is then deposited over the substrate 70 as shown in FIG. 3E. Thus, this active layer is formed such that electrical contact is made between the organic light-emitting layer and each of the one or more electrodes 72a, 72b, without forming electrical contact with the one or more vias 74a, 74b. Thus, a first light-emitting layer is formed in electrical contact with a first array of electrodes. The material forming the organic light-emitting layer in this example can be a small molecule organic light-emitting layer, which can be quite sensitive to the presence of oxygen or moisture. Therefore, this step can be performed within a vacuum using vapor deposition. In devices where the organic light-emitting layer 84 is a small molecule layer it can include several sublayers, including a hole transport layer a light-emission layer and an electron transport layer. A very thin, typically less than 50 nm, metal or metal oxide layer can optionally be formed over the organic layer. For example, a very thin layer of MgAg can be deposited. This layer can support electron injection but more importantly to this process, it can form a mechanical stabilizing layer to prevent mechanical damage to the small molecule organic light-emitting layer in subsequent steps. Note that it is not required that the organic light-emitting layer be formed of small molecule organic material and it can alternately be composed of a polymeric organic light-emitting material in which case it can be spun coat or otherwise solvent coated across the substrate and dried. As such a layer can be cross-linked, it can be mechanically stable and deposition of the very thin metal or metal oxide layer is not useful in providing mechanical stabilization as it can be when applying an active layer of small molecule organic materials.

The substrate is then exposed to the first fluorinated solvent. This step can be performed in a dry nitrogen environment at near atmospheric pressure. This step removes the second pattern of the fluorinated photo-patternable layer, removing the fluorinated photo-patternable layer within areas 80a and 80b. As this layer is removed, the layers coated over it, including the non-fluorinated photo-patternable layer and the organic light-emitting layer 84 is removed in the areas of this second pattern. Therefore the one or more via connectors 74a, 74b are exposed as shown in FIG. 3F. A conductive layer 88, for example a doped metal oxide layer such as ITO, is then deposited over the substrate as shown in FIG. 3G. Note that this conductive layer forms electrical contact with both of the one or more via connectors 74a, 74b and the top of the light-emitting layer. As such, the conductive layer 88 can be capable of conducting current from the one or more vias 74a, 74b to the top of the first light-emitting layer and can serve as a second electrode. This step can be performed in a dry nitrogen environment at near atmospheric pressure. This step can also be conducted in a vacuum. Note that it is important that the organic material be deposited between the via connectors and each electrode, further the distance between the connectors and the electrode should be larger than the thickness of the organic light-emitting layer such that the resistance between the via connectors and the electrodes is minimized when the current passes through the diode that is formed between the conductive layer 88 and the electrodes 72a, 72b. This is useful to prevent current from flowing from the via connectors 74a, 74b and the electrodes 72a, 72b without passing through the diode and permitting light emission. Further, note that while electrical connections are formed from the via connectors to the top of the organic layers in this step, the current cannot be independently controlled to each light-emitting element, the area of which is defined by each electrode 72a, 72b as these electrodes are all connected. Therefore, the current can flow between light-emitting elements creating crosstalk between these elements.

To avoid the crosstalk, the substrate is exposed to the second fluorinated solvent. Again, this step can be performed in a dry nitrogen environment at near atmospheric pressure. This solvent removes the third pattern within the fluorinated photo-patternable layer and all layers that have been subsequently deposited on top of it. Thus, the organic material and the second electrode is removed between each effective light-emitting element, leaving only areas 90a and 90b as shown in FIG. 3H. This step completes the patterning. Note that according to certain aspects of the present invention, the first active layer, namely the organic light-emitting layer has received a first pattern, that includes openings for the via connectors and the areas between subpixels corresponding to the second and third patterns. That is regions 80a, 80b and 82 have been removed from the light-emitting layer. Further, the second active layer, namely the conductive layer 88 has received a different pattern, being continuous except for the areas between subpixels corresponding to the third pattern. That is area 82 has been removed from the conductive layer. Thus this organic device has been constructed by depositing a fluorinated photo-patternable layer over a substrate, forming a first and a second active layer over the substrate, at least one of the first or second active layers including an active organic layer, and applying the photo-patternable layer to form a first pattern within the first active layer and a second, different pattern within the second active layer.

To complete the device, a bi-layer 92 including a second organic light-emitting layer and a final conductive layer, serving as a sheet electrode, are deposited over the substrate. This step can be performed in a dry nitrogen environment at near atmospheric pressure or, if vapor depositing organic small molecule materials can be performed in a vacuum coater. In this configuration, the voltage can be controlled independently to the portion of the first and second electrodes within each light-emitting element to independently control current to each layer of the OLED device. This method can provide a very high resolution OLED device with two colors of emission through a simple patterning process. In some configurations, one of the organic light-emitting layers can be deposited through a pair of shadowmasks to provide a full color device. Alternatively, color filters can be applied with the device to form a full color device.

Note that as described, the OLED device is composed of several individually controlled pixels, permitting the OLED device to function as a display or lamp. One skilled in the art will however, recognize that this control is not necessary for all OLED devices and can therefore be simplified within some embodiments and especially for some OLED lamps which can provide control of the two layers to permit the color of light to be adjusted.

As noted earlier, each light-emitting layer can be composed of either small molecule or polymer organic materials. In one embodiment, it can be desirable for the first light-emitting layer to be formed from polymer light-emitting materials as these materials can be more robust to the steps of the current process than small molecule light-emitting materials. Further, because polymeric materials are typically applied at near atmospheric pressure while small molecule materials are typically applied in a vacuum, forming this first light-emitting layer from a polymer reduces the number of transitions between a vacuum and atmospheric pressure environment, which can be time consuming and costly. For example, a green polymeric light-emitting material can be applied as the first light-emitting layer through spin, hopper or other solution coating means. However, to improve the overall efficiency of the device, it can be desirable for the second light-emitting layer to be formed from small molecule materials. For example, this layer can include a magenta light-emitting layer or include both red and blue light-emitting materials that is formed from small molecule light-emitting materials. This can be important as the small molecule red and blue light-emitting materials are typically more efficient than comparable polymeric materials and further the lifetime of the blue small molecule organic light-emitting materials is typically significantly longer than the lifetime of the blue polymer organic light-emitting materials.

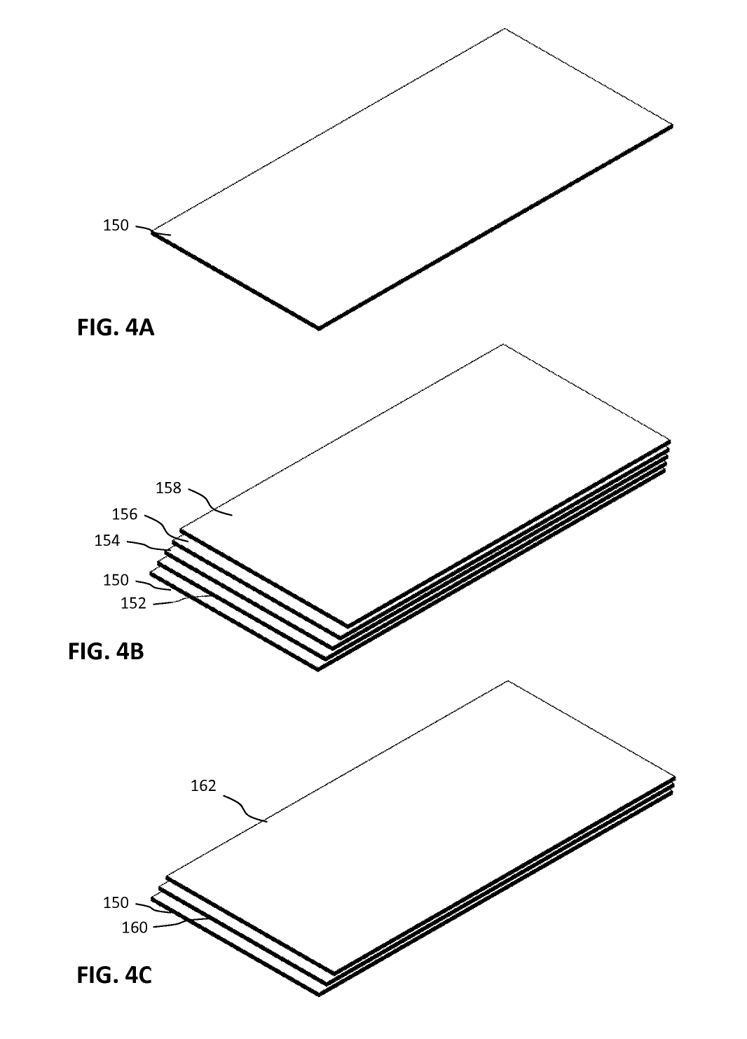

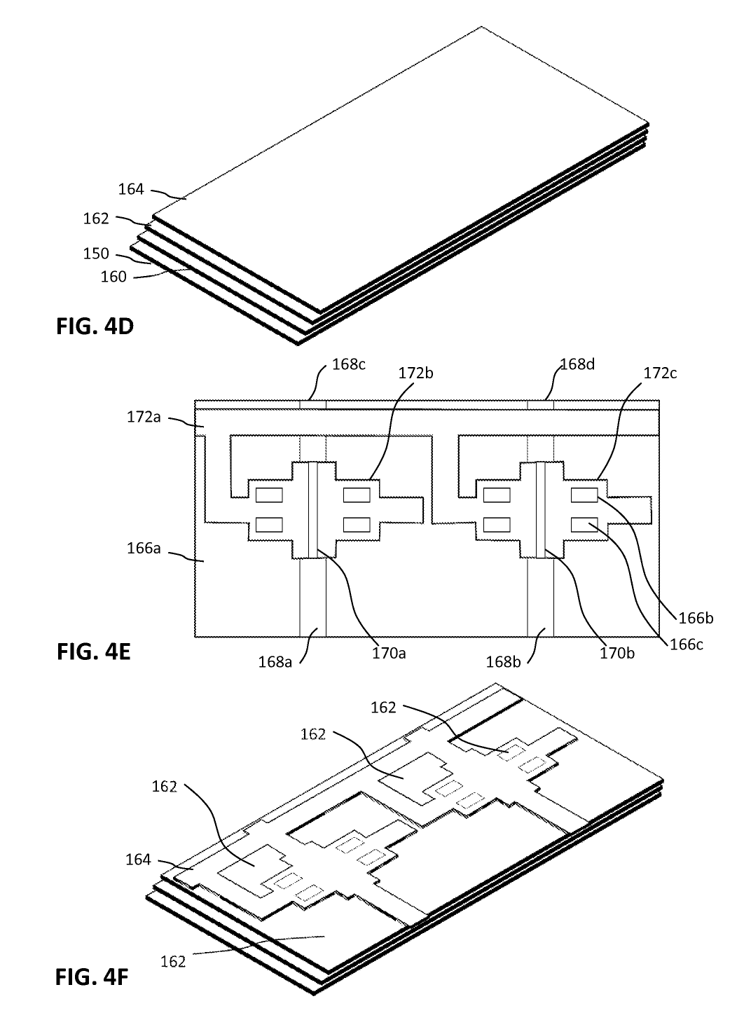

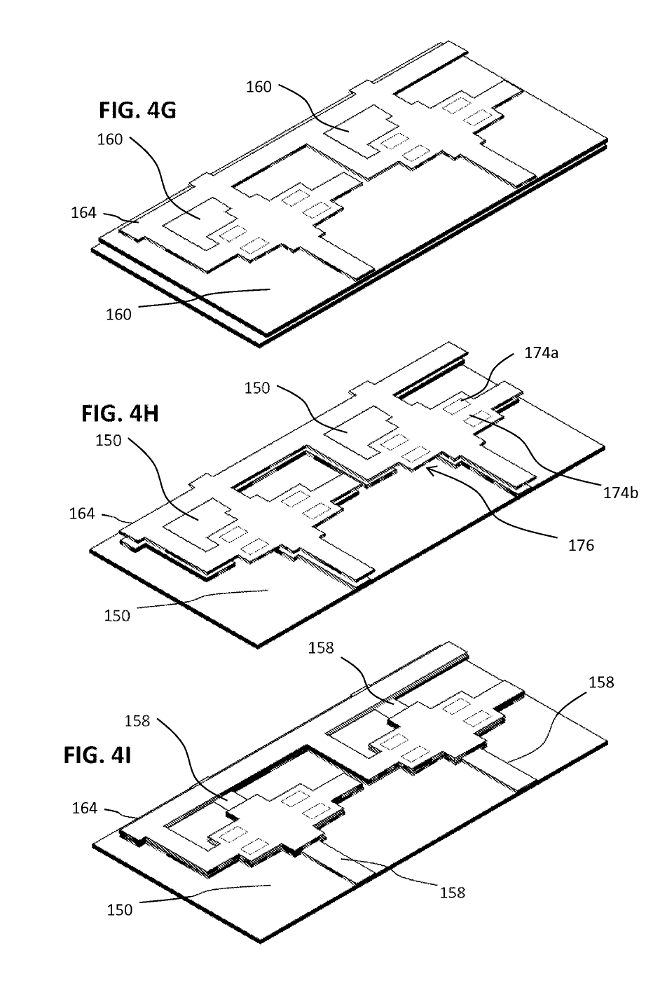

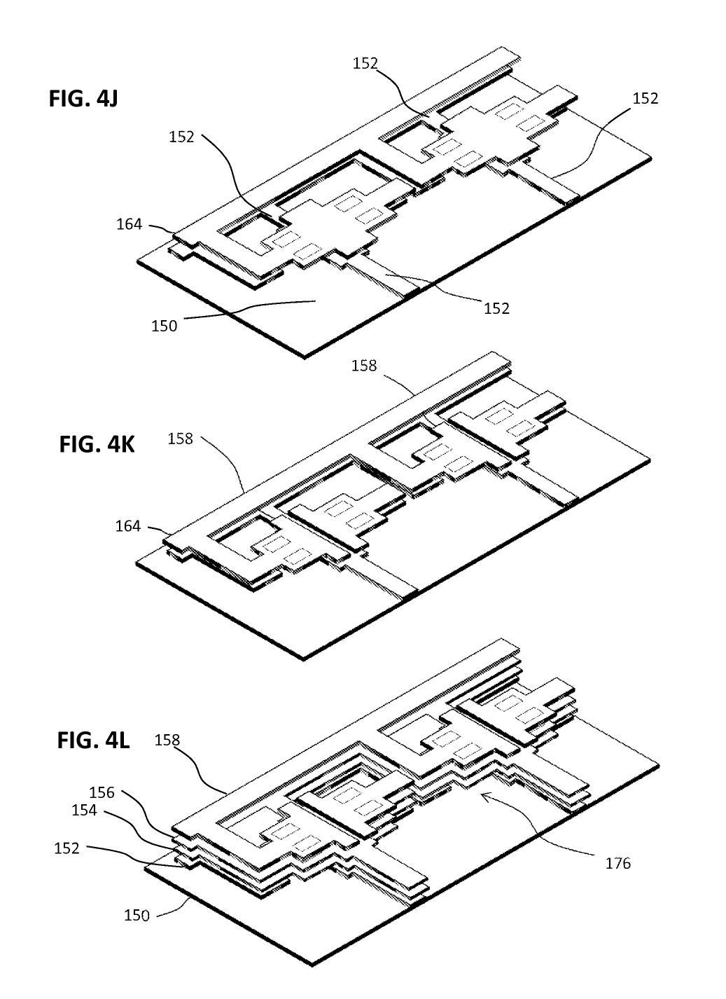

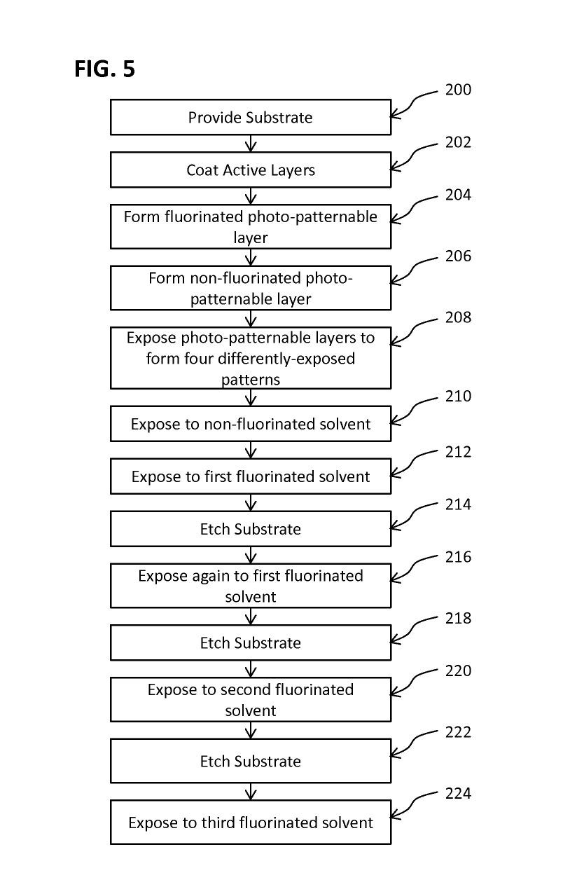

In another embodiment of the present invention, an array of one or more inorganic thin film transistors are formed using an etching, rather than a liftoff, process to provide the desirable electrical component. The steps used to form a particular device containing an array of one or more bottom gate TFTs are depicted in the process diagram of FIG. 4 and listed in the flow diagram of FIG. 5. While it should be noted that the particular device depicted and discussed here includes an array of bottom gate, inorganic TFTs, one skilled in the art will recognize that this the current invention is not limited to this particular embodiment and other devices, including top gate, organic TFTs or other patterned solid state electronics elements could be formed using the methods of the present invention.

As shown in FIG. 4A, a substrate 150 is provided 200 as shown in FIG. 5. The active layers useful in forming the TFTs within the device are then blanket coated 202 across the substrate as shown in FIG. 4B. These layers can include a first conductive metal layer 152 deposited near the substrate, a dielectric layer 154 deposited over the first conductive metal layer, a semiconducting layer 156 deposited over the dielectric layer, and a second conductive metal layer 158 deposited over the semiconducting layer. Within the current embodiment, it is useful for the first conductive metal layer to be formed from a different material from the second conductive metal layer. For example, the first conductive metal layer 152 can be formed of chrome and the second conductive metal layer 158 can be formed of aluminum.

For simplification purposes FIG. 4C shows these active layers 152, 154, 156, 158 as a single layer 160. Once these layers are deposited on the substrate 150, a fluorinated photo-patternable layer 162 is formed 204 over the active layers 160. Then, as shown in FIG. 3D, a non-fluorinated photo-patternable layer 164 is formed 206 over the fluorinated photo-patternable layer. Together the fluorinated and non-fluorinated photo-patternable bi-layer provide a photo-patternable bi-layer. Once this photo-patternable bi-layer has been created and dried as described earlier, it is exposed 208 to multiple levels of radiation, in this example the photo-patternable bi-layer is exposed to four different levels of radiation, to create four different patterns within the photo-patternable bi-layer.

In the current arrangement, the first pattern includes the areas outside the effective TFT structure, including area 166a as depicted in FIG. 4E. In the present arrangement, this first pattern 166 also includes areas 166b and 166c as shown in FIG. 4E. These areas provide access to the first metal conductive layer for later etching steps. Four similar areas are indicated in FIG. 3E for each of the two TFTs that will be illustrated. The second pattern 168 is exposed, such that the non-fluorinated photo-patternable layer 166 is exposed to radiation while the underlying fluorinated photo-patternable layer 162 is not exposed to radiation. In FIG. 4E, this pattern is indicated by areas 168a, 168b, 168c, 168d. The portions of this second pattern 168 indicated by areas 168a, 168b, 168c, and 168d, can be used to remove the second metal layer from the structure within these areas. The semiconductor and dielectric can also be optionally removed in these areas. The third pattern includes areas 170a, and 170b, which can provide the channels for the bottom gate TFTs of the current arrangement. This third pattern 170 can be exposed such that both the non-fluorinated photo-patternable layer 164 and the fluorinated photo-patternable layer can be exposed. However, the fluorinated photo-patternable layer can be exposed to a first amount of radiation. Finally, the remaining areas, including 172a, 172b, and 172c are included within a fourth pattern 172. This pattern is exposed such that both the non-fluorinated photo-patternable layer 164 and the fluorinated photo-patternable layer can be exposed. However, the fluorinated photo-patternable layer can be exposed to a second amount of radiation which is higher than the first amount of radiation.

The substrate is then exposed 210 to a non-fluorinated solvent, which removes the non-fluorinated photo-patternable layer 164 from the areas of the first pattern 166. This provides the structure illustrated in FIG. 4F with the non-fluorinated photo-patternable layer removed in the areas of the first pattern, exposing the fluorinated photo-patternable layer 162 outside the regions of the non-fluorinated photo-patternable layer 164. The Substrate 150 is then exposed 212 to a first fluorinated solvent for a first set of exposure conditions, including a first set of time, agitation and temperature conditions. This exposure, removes the fluorinated photoresist within the areas defined by the first pattern 166. As a result, the structure shown in FIG. 4G remains. As shown in FIG. 4G, both the fluorescent and non-fluorescent photo-patternable layers are removed within the first pattern, exposing the active layers 160. Both the fluorescent and the non-fluorescent photo-patternable layers remain in the areas defined by the second 168, third 170 and fourth 172 patterns.

The substrate is then etched 214 using any process capable of removing the active layers to remove the exposed materials within the second conductive metal layer 158, the semiconductor layer 156, and the dielectric layer 154. In one particular embodiment, the etching process can be an ion etching process and include either physical ion etching, also called dry etching, or assisted physical ion etching, referred to as wet etching. However, these particular etching processes are not required and one skilled in the art will recognize that a variety of different etch processes could be utilized without departing from the scope and spirit of the present invention. This etching is completed in such a way that at least the second conductive metal layer 158, the semiconductor layer 156, and the dielectric layer 154 are removed within the areas of the first pattern 166, using for example, a series of dry etch steps to remove each layer. A second etch step, preferably a wet etch step can be used to remove the first conductive metal layer 152. This step, not only removes the first conductive metal layer 152 in the areas within the first pattern 166 to expose the bare substrate in these areas, but it permits a significant undercut to be obtained, removing at least a portion of this first conductive metal layer outside the first pattern. This can be achieved using a wet etch step that employs an etchant that is highly selective to the first metal layer, softening this metal layer in the areas it contacts. Notice that the first pattern included areas 166b and 166c which are internal to a portion of the second conductive metal layer that is desired. These areas permit features, including 174a, 174b to be formed through the desired second conductive metal layer, the semiconducting layer and the dielectric layer by applying the solvents and the dry etching steps. These features 174a, 174b then permit the first conductive metal layer to exposed to the wet etching step such that the undercut created by this wet etching step can remove the first conductive metal layer within the regions of these features 174a, 174b, eliminating a portion of the first conductive metal layer near the TFT such as in the area 176 indicated in FIG. 4H. This permits the gate of the TFT to be isolated from the remaining portions of the first conductive metal layer to prevent shorting of this component. During both the dry and wet etching process, the photo-patternable bi-layer can protect the portion of each of the active layers within the second, third and fourth patterns from being removed by the etching process other than very thin features within the first conductive metal layer. This wet etching process can use chemicals that are selective to the material applied in the first conductive metal layer such that only this layer is affected by this process. A similar use of dry and wet etching have been described earlier by Taussig et al. in U.S. Pat. No. 7,202,179, issued on Apr. 10, 2007 and entitled “Method of forming at least one thin film device”.

The substrate can then be exposed 216 once again to the first fluorinated solvent for a second set of exposure conditions, including a first set of time, agitation and temperature conditions. This second set of exposure conditions can have a time longer than the duration of the first set of exposure conditions. This exposure can permit the first fluorinated photo-patternable layer 162 to lift off, removing the overlying non-fluorinated photo-patternable layer 164 and exposing the second conductive metal layer 158 in the areas within the second pattern. Once again, the substrate undergoes an etch 218, for example another dry etch, to remove at a least a portion of the active layers within the areas of the second pattern as shown in FIG. 4J. As shown in FIG. 4J, after the etch, the second conductive metal layer 158, the dielectric layer 156 and the semiconductor layer 154 can be removed leaving only the first conductive metal layer 152 within the areas of the second pattern, however, in some arrangements at least a portion of at least the dielectric layer 154 can be left over the first conductive metal layer at the completion of this etching step.

The substrate can then be exposed 220 to a second fluorinated solvent for a set of exposure conditions. This second solvent can permit the first fluorinated photo-patternable layer 162 to lift off, removing the overlying non-fluorinated photo-patternable layer 164 and exposing the second conductive metal layer 158 in the areas 170a, 170b of the third pattern as shown in FIG. 4K. Once again, a dry etch is applied 222, which removes the second conductive metal layer 158 within the areas 170a, 170b.

Finally, the substrate can then optionally be exposed 224 to a third fluorinated solvent for a set of exposure conditions. This third fluorinated solvent strips the remaining fluorinated photo-patternable layer 162, removing the remaining portions of the non-fluorinated photo-patternable layer 164. The final structure is shown in FIG. 4L. This structure includes a substrate 150. Over this substrate at least the first conductive metal layer 152 and the second conductive metal layer 158 are patterned differently as a result of applying a single photolithographic step that included depositing the photo-patternable bi-layer and a single exposure step which exposed the photo-patternable bi-layer to three or more, in this example four, different levels of exposure to create four separate patterns within the photo-patternable bi-layer. As shown, the first conductive metal layer is patterned to provide only two connections to the gate, removing material in other areas, including area 176. Over this the dielectric layer 154 and semiconductor layer 156 are patterned, in this case these two active layers receive the same pattern, however, the pattern imparted to the dielectric layer 154 and the semiconductor layer 156 is different than the patterns imparted to either the first conductive metal layer 152 or the second conductive metal layer.

Through the patterning steps that are provided, the pattern imparted to the first conductive metal layer 152 permits it to function to provide the gate and the data lines for an array of TFTs on a substrate. The pattern imparted to the dielectric layer permits it to prevent the flow of current from the first conductive metal layer 152 to the semiconductor layer 156. The semiconductor layer bridges the source and drain that are created in the second conductive metal layer through the formation of areas 158, which serves as the channels for the TFTs in the array.

As has been described, a method has been provided for forming a device, specifically an array of TFTs, wherein this method included providing a substrate; depositing a fluorinated photo-patternable layer over the substrate; forming a first and a second active layer over the substrate; and applying the photo-patternable layer to form a first pattern within the first active layer and a second, different pattern within the second active layer. This method permitted the formation of different patterns in the different active layers by depositing a non-fluorinated photo-patternable layer over the substrate to form a functional photo-patternable bi-layer with the fluorinated photo-patternable layer and exposing the photo-patternable bi-layer to a radiation source providing three or more distinct levels of radiation to create three or more patterns within the photo-patternable bi-layer. In this method a first non-fluorinated solvent was applied to remove a pattern of the non-fluorinated material within the non-fluorinated photo-patternable layer and at least two separate fluorinated solvents are applied to independently remove the fluorinated material within the different patterns of the fluorinated photo-patternable layer. Further, the first and second active layers were deposited on the substrate before the photo-patternable bi-layer and the step of applying the photo-patternable layer to form a first pattern within the first active layer and a second, different pattern within the second active layer included exposing the substrate to one or more solvents to remove the photo-patternable bi-layer within the first pattern within the photo-patternable bi-layer; exposing the substrate to a first etching process to remove at least a first portion of the first active layer within a first of the three or more patterns within the photo-patternable layer; exposing the substrate to one or more solvents to remove the photo-patternable bi-layer within a second pattern; and exposing the substrate to a second etching process to remove at least a second portion of the second active layer within a second of the three or more patterns within the photo-patternable layer. Specifically, the method included exposing the substrate to one or more additional solvents to remove the photo-patternable bi-layer within at least a third of the three or more patterns within the photo-patternable layer and patterning a first, second, and third active layer differently where these active layers included two conductive layers and a semi-conductor.

The preceding method for forming a thin-film transistor therefore included providing a substrate; coating active layers, including a first conductive layer, a dielectric layer, a semiconducting layer, and a second conductive layer, over the substrate; forming a photo-patternable layer including a fluorinated photo-patternable layer over the active layers; exposing the photo-patternable layer to a radiation source providing three or more different levels of radiation to different patterns within the photo-patternable layer; and exposing the photo-patternable layer to solvents to selectively remove the different patterns, applying one or more etching steps between the removal of the different patterns to provide the structural components of the TFT.

As described, certain aspects of the present invention provides a method for forming a device, including: providing a substrate; depositing a fluorinated photo-patternable layer over the substrate; forming a first and a second active layer over the substrate; and applying the photo-patternable layer to form a first pattern within the first active layer and a second, different pattern within the second active layer. Various embodiments of this method have been described herein. As illustrated by the examples, certain aspects of the invention enables the efficient creation of certain OLED display architectures that have not been realized through efficient processes within the prior art. Further, certain aspects of the invention provides a method for employing a single photo-lithographic step to form a structure including at thin film transistor on a substrate. These methods are facilitated by the observation that bi-layers of fluorinated and non-fluorinated photo-patternable layers can be formed and exposed to radiation and solvents to selectively remove the photo-patternable layer within three or more different areas within the photo-patternable layer. Further, these methods are facilitated by the observations that fluorinated photo-patternable layers can be employed and exposed to at least three different levels of radiation to create three different patterns and different solvents or exposure conditions to selectively remove material from these three different patterns. Further, the examples have illustrated that methods can be developed from these two observations, either singly or in combination to provide a method in which three or more patterns are created within a single photolithographic step to efficiently form high performance devices.

These high performance devices can be enabled because the photo-patternable layer can be deposited before one or more of the active layers and the patterns can be imparted to the active layer through liftoff. In other embodiments, the photo-patternable layer can be deposited after one or more of the active layers and the patterns can be imparted to the active layer through etching. In some embodiments, the step of exposing the photo-patternable layers to radiation can take place in environments containing oxygen or water. As these environmental factors can have a negative effect on the performance of certain organic and inorganic material layers, it is sometimes desirable that the photo-patternable layers be deposited and exposed prior to deposition of certain organic or highly reactive inorganic materials, including layers containing magnesium, lithium, and organic semiconductors, especially small molecule organic semiconductors.

The invention has been described in detail with particular reference to certain preferred embodiments thereof, but it will be understood that variations and modifications can be effected within the spirit and scope of the invention.

### LIST OF REFERENCE LABELS IN THE DRAWINGS

2 provide substrate step
4 deposit fluorinated photo-patternable layer step
6 form first active layer
8 form second active layer
10 apply photo-patternable layer to form patterns in active layers step
22 provide substrate step
24 form fluorinated photo-patternable layer step
26 form interlayer step
28 form non-fluorinated photo-patternable layer
30 expose to radiation step
32 bake substrate step
34 develop non-fluorinated photo-patternable layer step
36 expose to first fluorinated solvent step
38 deposit first active layer step
40 expose to second fluorinated solvent step
42 deposit second active layer step
44 expose to third fluorinated solvent step
46 deposit second active layer step
48 expose to fourth fluorinated solvent step
70 substrate
72a conductive electrode
72b conductive electrode
74a conductive via connector
74b conductive via connector
76 photo-patternable layer
78a area of first pattern
78b area of first pattern
80a area of second pattern
80b area of second pattern
82 area of third pattern
84 organic light-emitting layer
88 conductive layer
90a area
90b area
92 bi-layer of organic light-emitting layer and conductive layer
150 substrate
152 first conductive metal layer
154 dielectric layer
156 semiconducting layer
158 second conductive metal layer
160 combined single layer
162 fluorinated photo-patternable layer
164 non-fluorinated photo-patternable layer
166 first pattern
166a area within first pattern
166b area within first pattern
166c area within first pattern
168 second pattern
168a area within second pattern
168b area within second pattern
168c area within second pattern
168d area within second pattern
170 third pattern
170a area within third pattern
170b area within third pattern
172 fourth pattern
172a area within fourth pattern
172b area within fourth pattern
172c area within fourth pattern
174a feature
174b feature
176 area
200 provide substrate step
202 coat active layers step
204 form fluorinated photo-patternable layer step
206 form non-fluorinated photo-patternable layer step
208 expose photo-patternable layers to form four differently-exposed patterns step
210 expose to non-fluorinated solvent step
212 expose to first fluorinated solvent step
214 etch substrate step
216 expose to first fluorinated solvent step
218 etch substrate step
220 expose to second fluorinated solvent step
222 etch substrate step
224 expose to third fluorinated solvent step

1) A method for forming a device, including:
a. providing a substrate;
b. depositing a single fluorinated photo-patternable layer over the substrate;
c. forming a first and a second active layer over the substrate; and
d. applying the photo-patternable layer to form a first pattern within the first active layer and a second, different pattern within the second active layer.

2) The method of claim 1, wherein at least two separate fluorinated solvents are applied to independently remove portions of the fluorinated photo-patternable material to create the different patterns in the first and second active layers.

3) The method of claim 1, further including depositing a non-fluorinated photo-patternable layer over the substrate to form a functional photo-patternable bi-layer with the fluorinated photo-patternable layer.

4) The method of claim 3, further including depositing an interlayer between the fluorinated and non-fluorinated photo-patternable layer, wherein the interlayer influences the transmission of radiation.

5) The method of claim 3, further including exposing the photo-patternable bi-layer to a radiation source providing three or more distinct levels of radiation to create three or more patterns within the photo-patternable bi-layer.

6) The method of claim 5, wherein a first non-fluorinated solvent is applied to remove a pattern of the non-fluorinated material within the non-fluorinated photo-patternable layer.

7) The method of claim 6, wherein the first and second active layers are deposited on the substrate before the photo-patternable bi-layer and the step of applying the photo-patternable layer to form a first pattern within the first active layer and a second, different pattern within the second active layer includes:
a. exposing the substrate to one or more solvents to remove the photo-patternable bi-layer within the first pattern within the photo-patternable bilayer;
b. exposing the substrate to a first etching process to remove at least a first portion of the first active layer within a first of the three or more patterns within the photo-patternable layer;
c. exposing the substrate to one or more solvents to remove the photo-patternable bi-layer within a second pattern; and
d. exposing the substrate to a second etching process to remove at least a second portion of the second active layer within a second of the three or more patterns within the photo-patternable layer.

8) The method according to claim 7, further including exposing the substrate to one or more additional solvents to remove the photo-patternable bi-layer within at least a third of the three or more patterns within the photo-patternable layer.

9) The method according to claim 8, further including forming at least a third active layer over the substrate and wherein the photo-patternable layer is applied to form a first pattern within the first active layer; a second, different pattern within the second active layer and a third pattern within the third active layer which is different from the first or second patterns.

10) The method according to claim 9, wherein the first, second, and third active layers include two conductive layers and a semi-conductor.

11) The method of claim 6, wherein the first and second active layers are deposited on the substrate after the photo-patternable bi-layer and the step of applying the photo-patternable layer to form a first pattern within the first active layer and a second, different pattern within the second active layer includes:
a. exposing the substrate to a non-fluorinated solvent and a first fluorinated solvent to remove the photo-patternable bi-layer within the first pattern of the photo-patternable bilayer;
b. depositing the first active layer over the substrate;
c. exposing the substrate to a second fluorinated solvent to remove the photo-patternable bi-layer within a second pattern, lifting off the first active layer within the areas defined by the second pattern;
d. depositing the second active layer of the substrate; and
e. exposing the substrate to a third fluorinated solvent to remove the photo-patternable bi-layer within the third pattern, lifting off the second active layer within the areas defined by the third pattern.

12) The method of claim 11, wherein the first active layer includes an organic semiconductor and the second active layer includes a conductor which performs the function of an electrode within the organic device.

13) The method of claim 12, wherein the device is an OLED device having two independently-addressable layers.

14) The method of claim 1, wherein at least one of the first and second active layers is an organic compound and the device is an organic device.

15) The method of claim 1, further including exposing the photo-patternable bi-layer to a radiation source providing three or more distinct levels of radiation to create three or more patterns within the photo-patternable bi-layer.

16) The method of claim 1, wherein the radiation source exposes different areas within the fluorinated photo-patternable layer to three or more distinct levels of radiation and wherein the radiation source includes:
a. an area source and a density mask;
b. a projected light source and a density mask;
c. a collimated source and a holographic film for exposing different; or
d. a modulated point source.

17) The method of claim 3, wherein the radiation source provides light having spectral emission wherein the spectral emission includes a single peak wavelength and wherein both the fluorinated photo-patternable layer and the non-fluorinated photo-patternable layer are responsive to the peak wavelength of the radiation source.

18) The method of claim 3, wherein the radiation source provides light having spectral emission wherein the spectral emission includes two peak wavelengths and wherein the fluorinated photo-patternable layer and the non-fluorinated photo-patternable layer are differentially sensitive to the two peak wavelengths and the amplitude of each peak wavelength is modulated to independently control the exposure of the fluorinated photo-patternable layer and the non-fluorinated photo-patternable layer.

19) (canceled)

20) A method for forming an organic light-emitting diode device including:
a. providing a substrate including an array of electrodes connected to a power buss and an array of via connectors connected to a power buss;
b. depositing a photo-patternable layer over the substrate, the photo-patternable layer including a fluorinated photoresist material;
c. selectively exposing the photo-patternable layer to a first and a second dose of radiation to form a first pattern of exposed photoresist, a second pattern of differently exposed photoresist and a third pattern of unexposed photoresist;
d. exposing the substrate to a first solvent to remove the third pattern of unexposed photoresist, exposing one or more of the electrodes on the substrate;
e. forming an organic light-emitting layer over the substrate such that a portion of this layer is formed in electrical contact with the one or more exposed electrodes;
f. exposing the substrate to a second, fluorinated solvent to remove the first pattern of exposed photoresist material, forming a pattern in the organic semiconductor layer and exposing one or more of the via connectors;
g. depositing a conductor over the organic light-emitting layer to form a conductor layer such that the conductor layer forms an electrical connection with the via connectors; and
h. exposing the substrate to a third, fluorinated solvent to remove the second pattern of exposed photoresist material, patterning the conductor layer.

21) (canceled)

22) (canceled)

23) (canceled)

24) (canceled)

25) A method for forming a thin-film transistor including:
a. providing a substrate;
b. coating active layers, including a first conductive layer, a dielectric layer, a semiconducting layer, and a second conductive layer, over the substrate;
c. forming a photo-patternable layer including a fluorinated photo-patternable layer over the active layers;
d. exposing the photo-patternable layer to a radiation source providing three or more different levels of radiation to different patterns within the photo-patternable layer; and
e. exposing the photo-patternable layer to solvents to selectively remove the different patterns, applying one or more etching steps between the removal of the different patterns to provide the structural components of the TFT.
